(19) United States
(12) Patent Application Publication
(10) Pub. No.: US 2025/0194197 A1
(43) Pub. Date: Jun. 12, 2025

(54) GATE TIE-DOWN TO BACKSIDE POWER RAIL

(71) Applicant: International Business Machines Corporation, Armonk, NY (US)

(72) Inventors: Ruilong Xie, Niskayuna, NY (US); Lawrence A. Clevenger, Saratoga Springs, NY (US); Brent A. Anderson, Jericho, VT (US); Nicholas Anthony Lanzillo, Wynantskill, NY (US); Albert M. Chu, Nashua, NH (US); David Wolpert, Poughkeepsie, NY (US)

(21) Appl. No.: 18/532,556

(22) Filed: Dec. 7, 2023

(51) Int. Cl. H01L 29/66; H01L 21/8234; H01L 23/528; H01L 27/088; H01L 29/06; H01L 29/08; H01L 29/423; H01L 29/775; H01L 29/786

(52) U.S. Cl. CPC H10D 64/017; H01L 23/5286; H10D 30/014; H10D 30/43; H10D 30/6735; H10D 30/6757; H10D 62/121; H10D 62/151; H10D 84/0135; H10D 84/0149; H10D 84/038; H10D 84/83

(57) ABSTRACT

A semiconductor device includes a gate metal and a gate extension disposed within a region between two transistors of opposite conductivity and connected to the gate metal. The gate extension extends toward a side of the semiconductor device having power rails. A gate cut is disposed within the gate metal and through the gate extension to cut the gate extension into portions that are electrically isolated from each other. Each of the portions of the gate extension is coupled to a backside power rail.

### BACKGROUND

The present invention generally relates to semiconductor devices and processing methods, and more particularly to a backside gate contact connection to a backside power rail using local interconnect structures.

Backside power rails are provided to supply power and ground to transistors devices on a chip. Conventions dictate that one of the most convenient placements for a backside power rail is in an N2N space, i.e., under but between adjacent n-type field effect transistors (NFETs), and a P2P space, i.e., under but between adjacent p-type field effect transistors (PFETs). This limits options for the placement of gate contacts, which are usually left with a location between NFET-PFET (N2P) regions. This makes connecting the gate by a gate tie-down to a backside power distribution network (BSPDN) very difficult especially in view of decreasing node sizes.

Therefore, a need exists for alternate gate connection methods and wiring that preserves the electrical integrity of conductive components but provides efficient wire routing within the constraints of ever decreasing node sizes.

### SUMMARY

In accordance with an embodiment of the present invention, a semiconductor device includes a gate metal and a gate extension disposed within a region between two transistors of opposite conductivity and connected to the gate metal. The gate extension extends toward a side of the semiconductor device having power rails. A gate cut is disposed within the gate metal and through the gate extension to cut the gate extension into portions that are electrically isolated from each other. Each of the portions of the gate extension is coupled to a backside power rail.

In some embodiments, the gate extension can be disposed within a shallow trench isolation. Each of the portions of the gate extension can be connected to a local interconnect. The local interconnect can connect a portion of the gate extension to a corresponding backside power rail. The gate extension can extend toward a back side of the semiconductor device, and the local interconnects can be disposed within a layer for back side contacts. A source/drain region connected to a top side contact can be separated from the local interconnects by a backside interlevel dielectric layer. Source/drain regions of the two transistors of opposite conductivity can have the gate cut disposed therebetween.

In accordance with another embodiment of the present invention, a semiconductor device includes an N-type field effect transistor (NFET), a P-type field effect transistor (PFET) disposed adjacent to the NFET and a gate metal disposed in a region between the NFET and the PFET. A gate extension is disposed within the region between the NFET and the PFET and connected to the gate metal on a back side of the semiconductor device. A gate cut is disposed through the gate metal, and through the gate extension to cut the gate extension into a first portion and a second portion that are electrically isolated from each other. The first portion is coupled to a first backside power rail, and the second portion is coupled to a second backside power rail.

In some embodiments, the gate extension can be disposed within a shallow trench isolation. The first portion of the gate extension can connect to a supply voltage backside power rail through a local interconnect, and the second portion of the gate extension can connect to a grounded backside power rail through a local interconnect. The gate cut can be disposed between source/drain regions of the NFET and the PFET. Additional gate cuts can be disposed between source/drain regions having a same conductivity. The first portion can be coupled to the first backside power rail with a first local interconnect, and the second portion can be coupled to the second backside power rail with a second local interconnect. The first local interconnect and the second local interconnect can be disposed within a layer for backside contacts. A source/drain region connected to a top side contact can be separated from a corresponding one of the first local interconnect and the second local interconnect by a backside interlevel dielectric layer.

In accordance with another embodiment of the present invention, a method for fabrication of a semiconductor device includes extending a gate electrode by forming a gate extension into a shallow trench isolation (STI) region at an NFET to PFET (N2P) boundary; cutting the gate extension into portions by forming a gate cut through gate extension to divide gate extension; forming backside local interconnects to connect to the portions of the gate extension; and forming power rails to connect to the backside local interconnects to tie-down the gate electrode.

In other embodiments, the backside local interconnects can be formed by depositing a conductor in an opening separated by the gate cut. The method can include forming additional gate cuts disposed between source/drain regions having a same conductivity. The backside local interconnects can be formed within a layer for backside contacts and a source/drain region connected to a top side contact can be separated from a corresponding backside local interconnect by a backside interlevel dielectric layer.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows cross-sectional views, taken at section lines X, Y1, Y2 and Y3 as shown in an inset (and referred to as section X, section Y1, section Y2, and section Y3 respectively), of a semiconductor substrate with shallow trench isolation formed and a patterned stack of layers that can be formed or provided in one or more nanosheets, in accordance with an embodiment of the present invention;

FIG. 2 shows cross-sectional views, taken at section lines X, Y1, Y2 and Y3, of an opening formed into the shallow trench isolation for a gate extension, in accordance with an embodiment of the present invention;

FIG. 3 shows cross-sectional views, taken at section lines X, Y1, Y2 and Y3, after formation of dummy gates and source/drain regions formed on sacrificial placeholders, in accordance with an embodiment of the present invention;

FIG. 4 shows cross-sectional views, taken at section lines X, Y1, Y2 and Y3, after formation of a top interlevel dielectric layer, etching trenches and filling the trenches to form gate cuts (or dielectric bars), in accordance with an embodiment of the present invention;

FIG. 5 shows cross-sectional views, taken at section lines X, Y1, Y2 and Y3, after further top interlevel dielectric material is added and patterned to form middle of the line contacts, back end of the line structures are formed; a carrier wafer is applied and structure is flipped to process the bottom side, in accordance with an embodiment of the present invention;

FIG. 6 shows cross-sectional views, taken at section lines X, Y1, Y2 and Y3, after the substrate has been removed to an etch stop layer, in accordance with an embodiment of the present invention;

FIG. 7 shows cross-sectional views, taken at section lines X, Y1, Y2 and Y3, after openings are formed by etching remaining portions of the semiconductor layer, in accordance with an embodiment of the present invention;

FIG. 8 shows cross-sectional views, taken at section lines X, Y1, Y2 and Y3, after a backside interlevel dielectric layer is formed, in accordance with an embodiment of the present invention;

FIG. 9 shows cross-sectional views, taken at section lines X, Y1, Y2 and Y3, after the backside interlevel dielectric layer is etched to open contact holes or trenches to expose the sacrificial placeholders at selected contact positions and for the formation of backside local interconnects, in accordance with an embodiment of the present invention;

FIG. 10 shows cross-sectional views, taken at section lines X, Y1, Y2 and Y3, after the exposed sacrificial placeholders are removed to expose portions of active regions and contact and local interconnects are formed, in accordance with an embodiment of the present invention; and

FIG. 11 shows cross-sectional views, taken at section lines X, Y1, Y2 and Y3, after forming backside power rails and a backside power distribution network, in accordance with an embodiment of the present invention.

### DETAILED DESCRIPTION

In accordance with embodiments of the present invention, devices and methods are described which include connecting gate structures to backside power rails. In useful embodiments, a gate extension is formed with a zone between an n-type field effect transistor (NFET) to p-type field effect transistor (PFET) (N2P). A gate cut or dielectric bar through the gate extension divides gate extension into two gate extension portions. A backside local interconnect is formed over the gate extension portions. Backside power rails are formed and connect to the backside local interconnects to tie-down (connect) the gate. The backside power rails provide positive supply voltage (VDD) or negative supply voltage (VSS) to respective gates for PFETS and NFETs.

In other embodiments, a semiconductor device includes backside local interconnects that connect a gate extension to backside power. The gate extension for an NFET and a gate extension for a PFET are separated by a dielectric bar that bifurcates or cuts the gate extension. The backside local interconnect for the NFET, and the backside local interconnect for the PFET are electrically separated by the dielectric bar to compactly provide gate connections through the tight N2P region in which the gate extension portions are located. In one embodiment, a source/drain connected to a frontside contact is separated from the backside local interconnect by a backside interlevel dielectric layer (BILD).

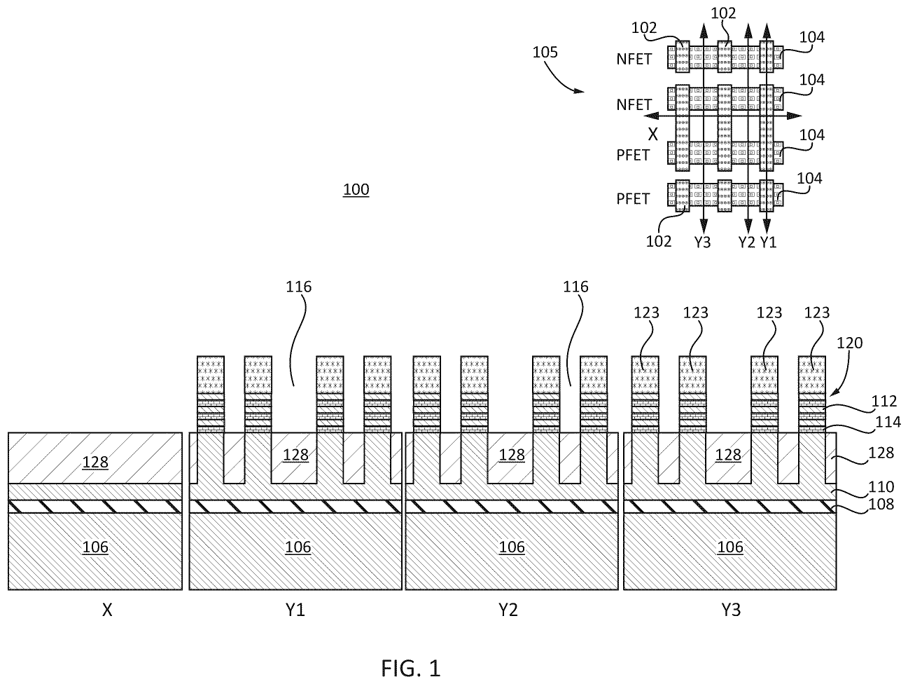

Referring now to the drawings in which like numerals represent the same or similar elements and initially to FIG. 1, devices and methods for manufacturing a nanosheet field effect transistor (FET) device are shown in accordance with embodiments of the present invention. A wafer 100 includes a substrate 106 having multiple layers on which a semiconductor device will be fabricated. FIG. 1 depicts cross-sectional views X, Y1, Y2 and Y3 taken at corresponding sections lines X, Y1, Y2 and Y3 in inset 105. Inset 105 shows gate lines 102 and active region lines 103, 104 for reference. Corresponding X, Y1, Y2 and Y3 views are depicted throughout FIGS. 1-11. Active region lines 103, 104 represent source/drain (S/D) regions for transistor devices to be formed, and gate lines 102 are represented for such transistor devices. Transistor channels are formed on the active region lines 103, 104 below the gate lines 102. In the illustrative embodiments shown, active region lines 103 are employed with NFETs and active region lines 104 are employed with PFETs.

The substrate 106 can include any suitable substrate structure, e.g., a bulk semiconductor, a semiconductor-on-insulator (SOI) substrate, etc., and preferably includes a monocrystalline semiconductor. In one example, the substrate 106 can include a silicon-containing material. Illustrative examples of Si-containing materials suitable for the substrate 106 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

An etch stop layer 108 is formed on the substrate 106. The etch stop layer 108 can include an epitaxially grown crystal structure. The etch stop layer 108 includes a material that permits the selective etching and removal the substrate 106 in later steps. In one embodiment, the etch stop layer 108 includes SiGe although depending on the material of the substrate 106, other materials can be selected, e.g., SiGeC, SiC, etc.

A semiconductor layer 110 is epitaxially grown on the etch stop layer 108. The semiconductor layer 110 can include a same material as the substrate 106, although other semiconductor materials can be employed, e.g., SiGe, SiGeC, SiC, etc.

A layer stack or stacks are applied to or formed on the semiconductor layer 110. In one embodiment, one or more nanosheets (NS) are applied to the semiconductor layer 110. In another embodiment, the layer stacks can be epitaxially grown using different chemistries to form layers having different properties. In an embodiment, a patterned layer stack 120 includes alternating semiconductor layers 112 and 114. Semiconductor layers 112 are selectively removeable relative to the semiconductor layers 114 and vice versa, e.g., by a selective etching process. In one embodiment, semiconductor layer 112 includes SiGe, where Ge can include, e.g., 30 atomic % of the compound, and semiconductor layer 114 can include Si. It should be understood that other materials or atomic percentages can be employed for semiconductor layers 112 and 114. In other embodiments, different stack orders and numbers of layers may be employed for semiconductor layers 112 and 114.

A single or multiple nanosheets or an epitaxial grown layer stack can include the stack 120 which can be patterned to expose and etch the semiconductor layer 110. In one embodiment, a hard mask 123 may be formed by blanket depositing a layer of hard mask material, providing a patterned photoresist on top of the layer of hard mask material, and then etching the layer of hard mask material to provide the hard mask pattern for etching the stack 120. The patterned photoresist can be produced by applying a blanket photoresist layer to the surface of the hard mask material and exposing the photoresist layer to a pattern of radiation, and then developing the pattern into the photoresist layer utilizing resist developer. The pattern in the photoresist layer is transferred to the hard mask by an etch process.

Openings 116 are formed through stack 120 using an anisotropic etch process, such as a reactive ion etch (RIE), or an ion beam etch (IBE). Semiconductor layer 110 is further etched to form shallow trenches therein in accordance with openings 116. Shallow trench isolation (STI) or STI 128 is formed in the etched trenches. STI 128 can be formed by depositing dielectric material, such as, e.g., SiO₂, SSiOₓN_{y}, SiCO or other suitable compounds. STI 128 can be deposited using chemical vapor deposition (CVD), although other deposition methods can be employed. The STI 128 can then be etched, e.g., by RIE, to a level of the semiconductor layer 110.

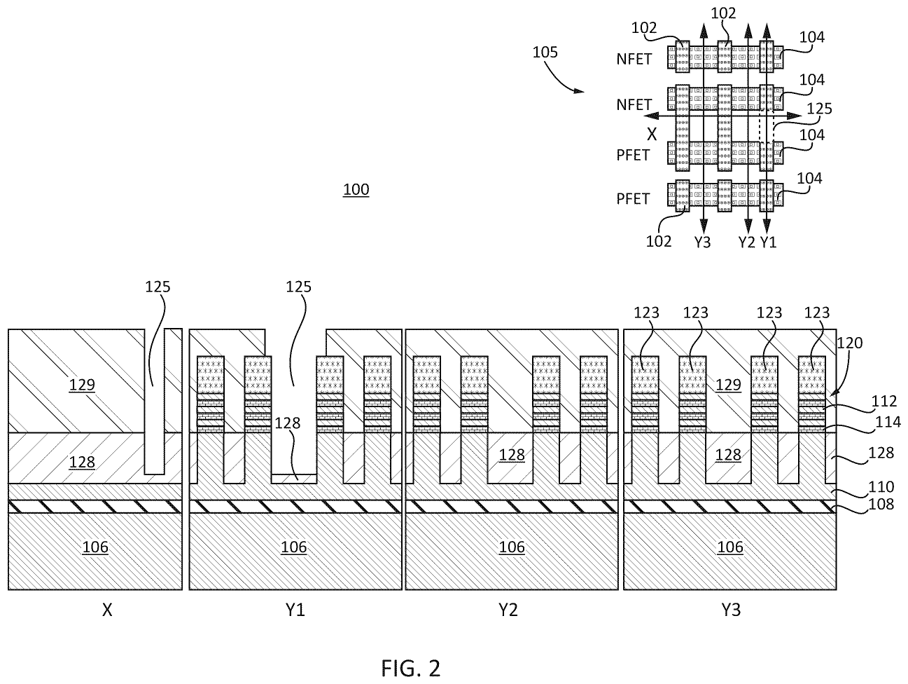

Referring to FIG. 2, a planarizing material 129 is blanketed over the wafer 100. The planarizing material 129 can include an organic planarization layer (OPL). The planarizing material 129 is patterned to locate a gate extension. In a particularly useful embodiment, the wafer 100 is processed to form a nanosheet field effect (FET) transistor device. The gate contact opening 125 can be employed for a gate extension region.

The planarizing material 129 is etched to open up opening 125. Then, etching continues into the STI 128 within the opening 125. The etch can include, e.g., RIE or IBE.

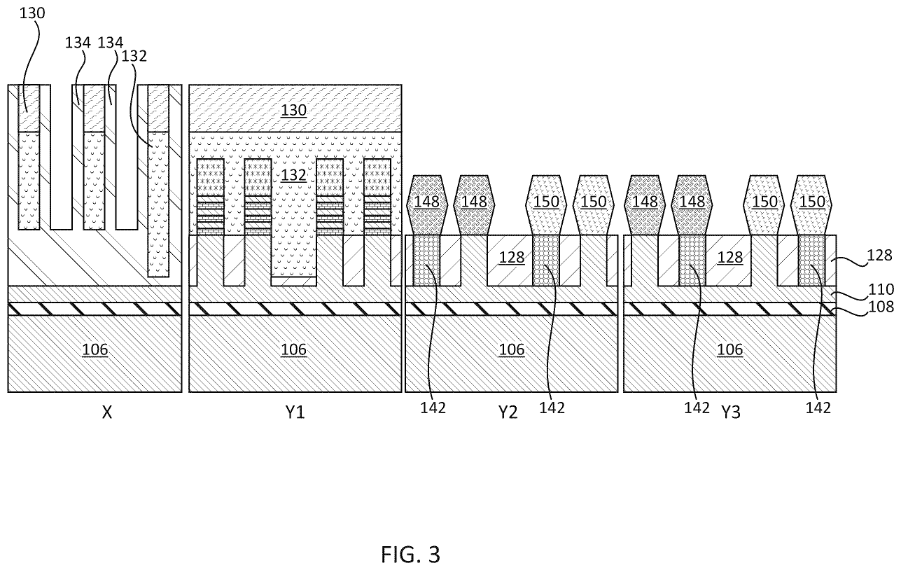

Referring to FIG. 3, a dummy gate material for dummy gates 132 is blanketed over the wafer 100 followed by a blanket deposition of a hard mask material to later form patterned hard mask 130, e.g., by using photolithographic patterning. The dummy gate material can include a polysilicon, amorphous Si or other selectively removeable material. The hard mask material is patterned to form hard mask 130. The hard mask 130 is employed to etch the dummy gates 132. Then, a deposition process is employed to form spacers 134. Spacers 134 can include a nitride, such as, e.g., SiN, SiBCN, SiOCN, SiOC, SiC, although other dielectric materials can be employed.

The hard mask 130 can be employed as an etch mask to recess the nanosheet (e.g., stack 120) to expose semiconductor layer 110. Regions of the nanosheet below the hard mask 130 and are patterned for further processing while the nanosheet (e.g., stack 120) is completely removed in other regions.

After nanosheet recess, exposed sacrificial sheets of the semiconductor layers 112 are indented (laterally recessed), and inner spacers (not shown) are formed and include a dielectric material. In one embodiment, the inner spacers are formed using exposed portions of the semiconductor layers 112, which undergo a Ge condensation process to form a dielectric oxide (SiO₂) at the exposed portions by a thermal oxidation process. The oxidation process converts SiGe to the dielectric material and condenses out Ge.

The hard mask 130 can be employed as an etch mask to recess the semiconductor layer 110. The semiconductor layer 110 is recessed to form trenches, e.g., by RIE. Within the trenches recessed into the semiconductor layer 110, a sacrificial placeholder 142 is formed. The sacrificial placeholder 142 can be epitaxially grown in the trenches of semiconductor layer 110. The sacrificial placeholder 142 can include SiGe or other epitaxial grown material that can be selectively removed relative to the semiconductor layer 110.

An epitaxial growth process is performed to form source and drain (S/D) regions 148 and 150. S/D regions 148 and 150 can include Si or SiGe and include faceted surfaces when epitaxial growth is not confined. In one embodiment, the S/D regions 148 and 150 can be designated as N-type or P-type devices, respectively, where N-type devices can include, e.g., Si and P-type devices can include, e.g., SiGe. The S/D regions 148 and 150 can be appropriately doped during formation by epitaxial growth. For example, the S/D region 150 can be doped by introducing p dopants (e.g., B, Ga, etc.) during epitaxial formation. Similarly, the S/D region 148 can be doped by introducing n dopants (e.g., P, As, etc.) during epitaxial formation. P-type and N-type devices can be formed adjacent to one another.

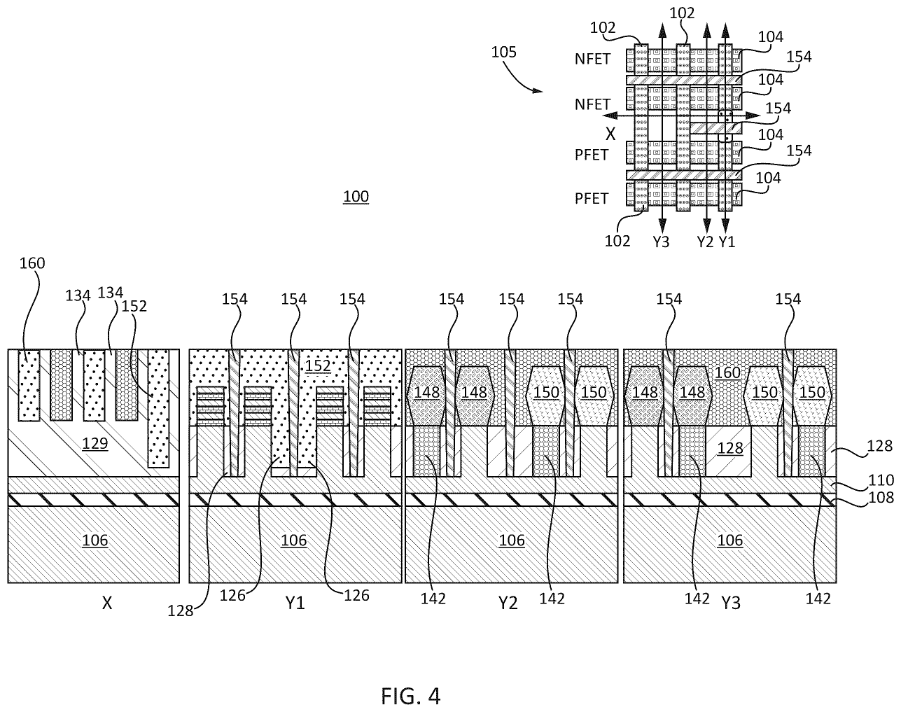

Referring to FIG. 4, a dielectric layer 160, such as, e.g., an interlevel dielectric layer (ILD) is formed on the wafer 100. The dielectric layer 160 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SILK™, other carbon containing materials, organo-inorganic materials such as spin-on glasses and silsesquioxane-based materials, and diamond-like carbon (DLC), also known as amorphous hydrogenated carbon, α-C:H). The dielectric layer 160 can be deposited using CVD, although other deposition methods can be employed.

Dummy gates 132 and semiconductor layers 112 are removed by etching. This can include separate etch processes. After that, replacement gate metal 152 is formed, which comprises a gate dielectric, such as, e.g., HfO₂, HfSiOₓ, HfAlOₓ, HfLaOₓ, etc., one or more layers of work function metal (WFM) and conductive metal fill, such as. e.g., W, Al, Ru.

Gate metal 152 is deposited into opening 125 (FIG. 2) to form a gate extension 126. The gate extension 126 extends into STI 128 and brings conductive material closer to a backside of the wafer 100.

In accordance with embodiments, of the present invention, gate cuts 154 are formed to separate and provide electrical isolation between structures. Gate cuts 154 are patterned using lithographic patterning techniques. For example, lithography can be employed to pattern an etch mask (not shown). Trenches for the gates cuts 154 are etched in accordance with the etch mask and then the gate cuts 154 are filled with a dielectric material and a free surface is planarized. The gate cuts 154 separate portions of gate extension 126 and separate S/D regions 148, 150 from each other. The gate cuts 154 can be formed down to the semiconductor layer 110. The gate cuts 154 can be formed into and through the STI 128. The gate cuts 154 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The gate cuts 154 can be deposited using CVD, plasma enhanced CVD (PECVD), although other deposition methods can be employed.

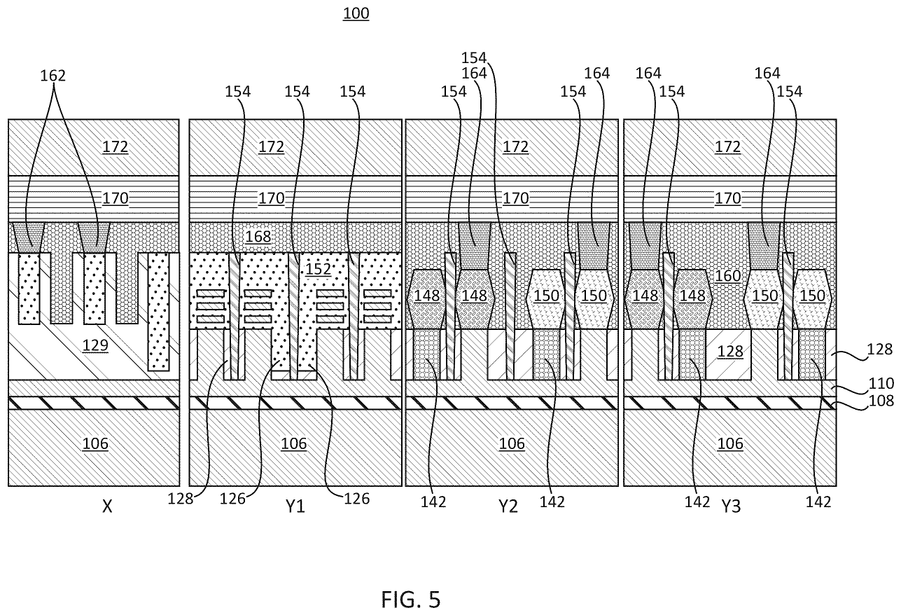

Referring to FIG. 5, middle of the line (MOL) contacts 162, 164 are formed to make connections with the S/D regions 148, 150 and the gate metal 152 on a top side of the wafer 100.

A dielectric layer 168 is formed on the wafer 100 and planarized. Trenches or holes are formed in the dielectric layer 168, which forms a top ILD. The trenches or holes expose the underlying active materials for the S/D regions 148 and 150 and can expose portions of the gate metal 152.

In useful embodiments, a silicide liner, such as Ti, Ni, NiPt is deposited first in the contact trenches, then a diffusion barrier can be formed in the contact trenches prior to a conductive fill. The diffusion barrier can include, e.g., TiN, TaN, or similar materials.

A conductive fill is performed to fill the trenches on top of the diffusion barrier, if present. The conductive fill can include materials, such as, e.g., Co, Cu, Ru, Mo, Rh, W, Ir, and alloys or combinations of these and other conductive materials. In a particularly useful embodiment, the conductive fill includes W. The conductive fill can be formed using a deposition method, such as, e.g., CVD, PECVD, atomic layer deposition (ALD) or any other suitable deposition method. The conductive fill is planarized, e.g., by CMP, to form contacts 162, 164.

Processing continues with the formation of back end of the line (BEOL) layer 170, which can include metal structures and dielectric layers to complete the top side of the device and provide electrical access to the devices formed. A carrier wafer 172 can be bonded to the BEOL layer 170. The carrier wafer 172 provides support and transportability to the wafer 100 for further processing which includes flipping the wafer 100 and removing portions of a bottom side of the device.

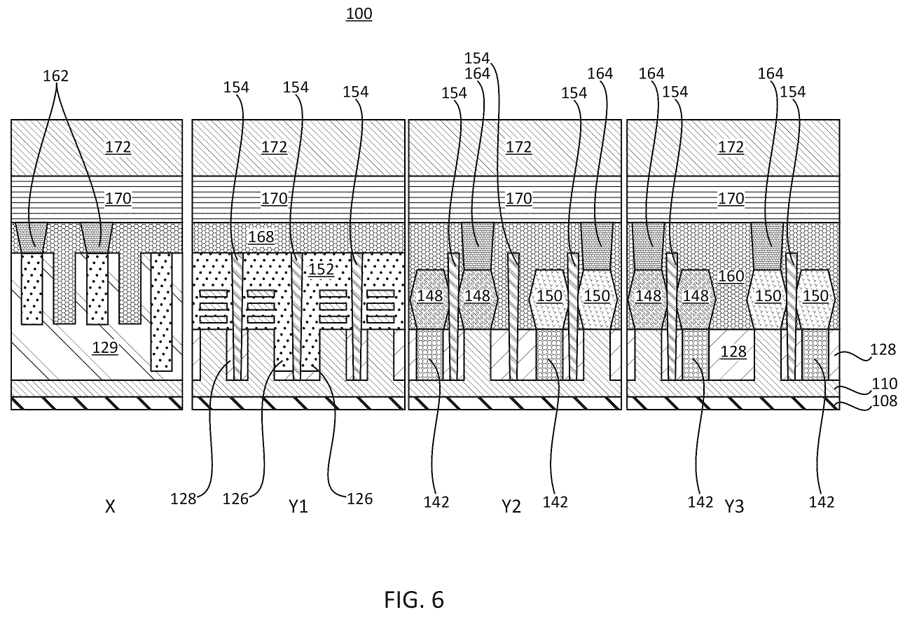

Referring to FIG. 6, to continue processing, the wafer 100 can be flipped to process features on the bottom side of the device. However, for clarity and consistency, the device will be shown in the FIGS. in a same orientation as previously described with continued and consistent reference to bottom/top. The substrate 106 is removed from the bottom side of the device. The substrate 106 can be removed by an etch process that stops on the etch stop layer 108. In an alternate embodiment, a cleave process can be employed to propagate a crack to remove the substrate 106 at the etch stop layer 108.

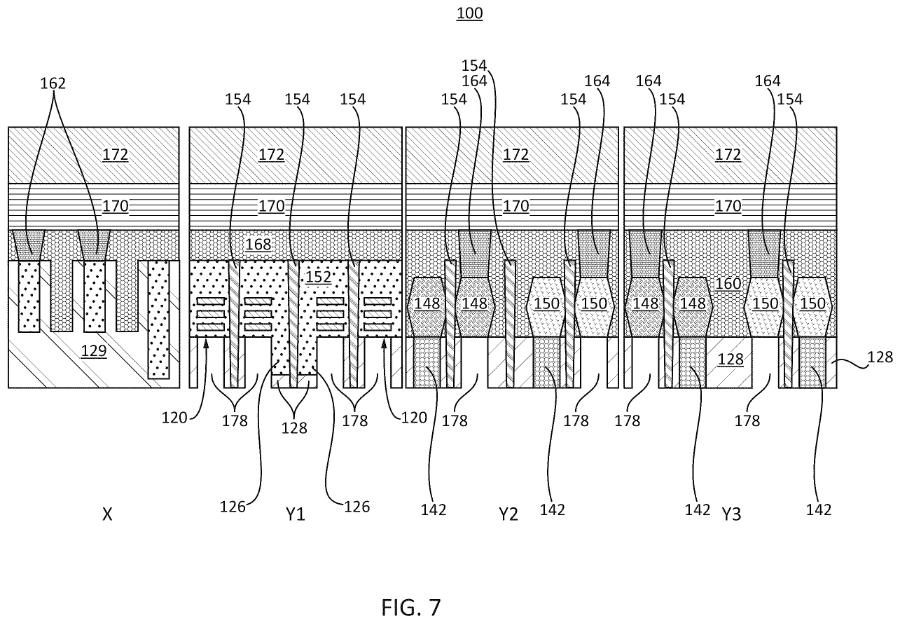

Referring to FIG. 7, the etch stop layer 108 is then removed by an etch process. In an alternate embodiment, a CMP process can be employed. With the removal of the etch stop layer 108, the semiconductor layer 110 is exposed. The semiconductor layer 110 is removed by an etch process that selectively removes the material of the semiconductor layer 110 relative to the STI 128, the sacrificial placeholders 142 or gate metal 152 (e.g., high-k metal). The removal of the semiconductor layer 110 forms openings 178.

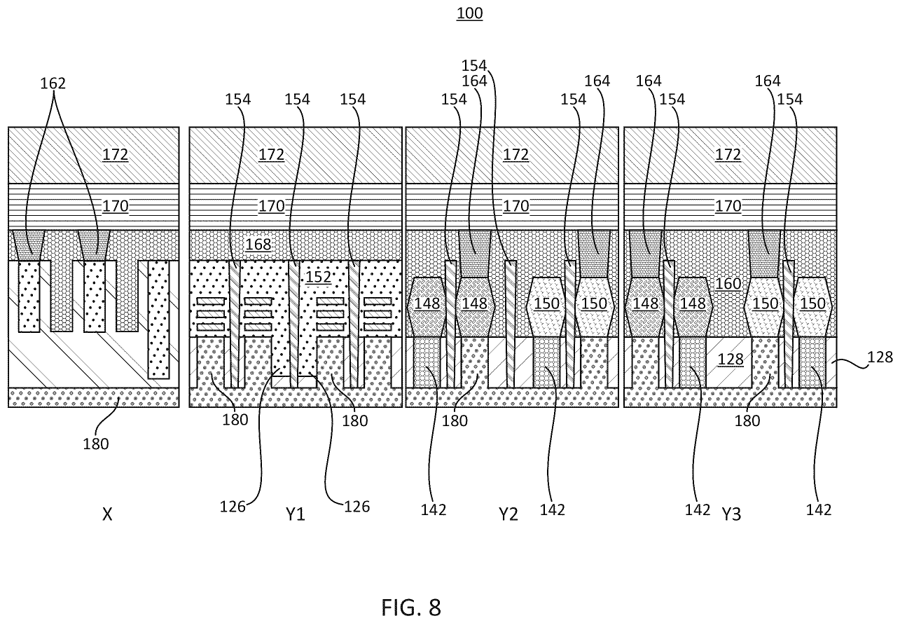

Referring to FIG. 8, a dielectric layer 180 is formed in the openings 178. The dielectric layer 180 includes a material that is selectively removeable relative to the gate cut 154 materials. In one embodiment, the dielectric layer 180 includes a form of silicon oxide. The dielectric layer 180 forms a backside ILD (BILD).

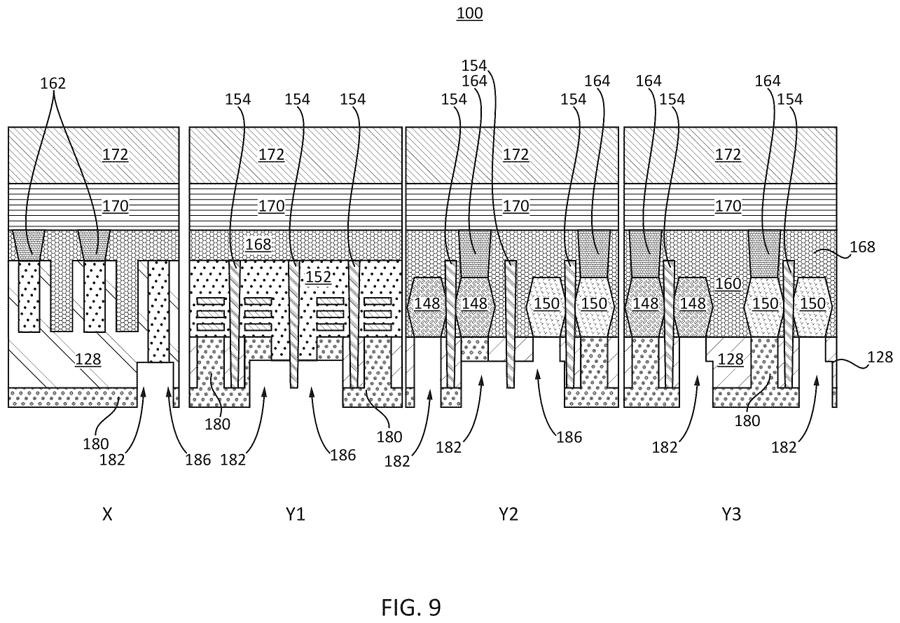

Referring to FIG. 9, backside contacts are located to make connections with the S/D regions 148 and 150 and gate metal 152. Openings 182 are formed in the dielectric layer 180. Openings 182 can be patterned using photolithographic patterning techniques to create an etch mask to etch the openings 182 with an anisotropic etch, e.g., RIE. Openings 182 expose the underlying sacrificial placeholders 142 corresponding to the S/D regions 148, 150.

In accordance with embodiments of the present invention, openings 182 are etched into the dielectric layer 180, STI 128 and the sacrificial placeholders 142 in accordance with a pattern to form the back contacts. In region 186 where a gate tie-down is to be formed, the opening 182 extends on sides of a gate cut 154. The gate cut 154 self-aligns a separation between portions of the region 186. Region 186 provides a region for the placement of a local interconnect as will be described.

The sacrificial placeholders 142 are recessed in regions where the sacrificial placeholders 142 have been exposed by etching. The etch process can include a dry etch or wet etch that selectively etches the sacrificial placeholders 142 relative to the S/D region 148, STI 128 and dielectric layer 180 to complete the openings for active region contacts. The corresponding S/D regions 148, 150 are now exposed through openings 182.

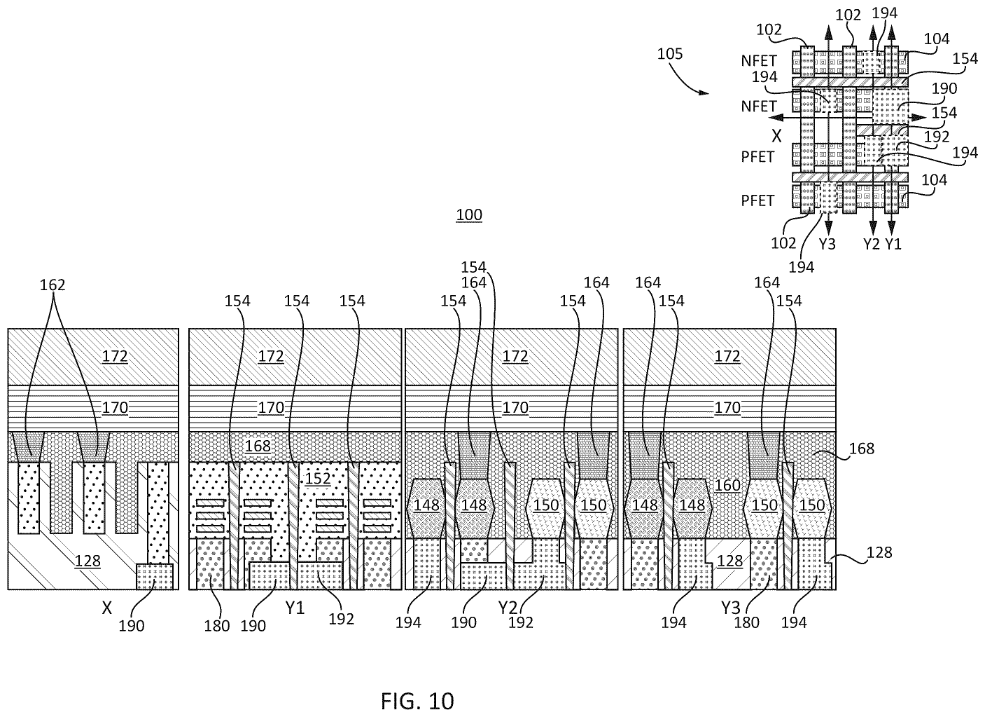

Referring to FIG. 10, in useful embodiments, a silicide liner, such as Ti, Ni, NiPt is deposited first, then a diffusion barrier can be formed in the openings 182 prior to a conductive fill. The diffusion barrier can include, e.g., TiN, TaN, or similar materials. A conductive fill is performed to fill the openings 182. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form local interconnects 190 and 192 as well as backside contacts 194.

The planarization process ensures distinct boundaries between local interconnect 190 and local interconnect 192. This is achieved by planarizing to remove conductive material from the gate cut 154 that divides the local interconnect 190 from local interconnect 192. The local interconnect 190 functions as a gate tie-down for an NFET (S/D region 148) and local interconnect 192 functions as a gate tie-down for a PFET (S/D region 150).

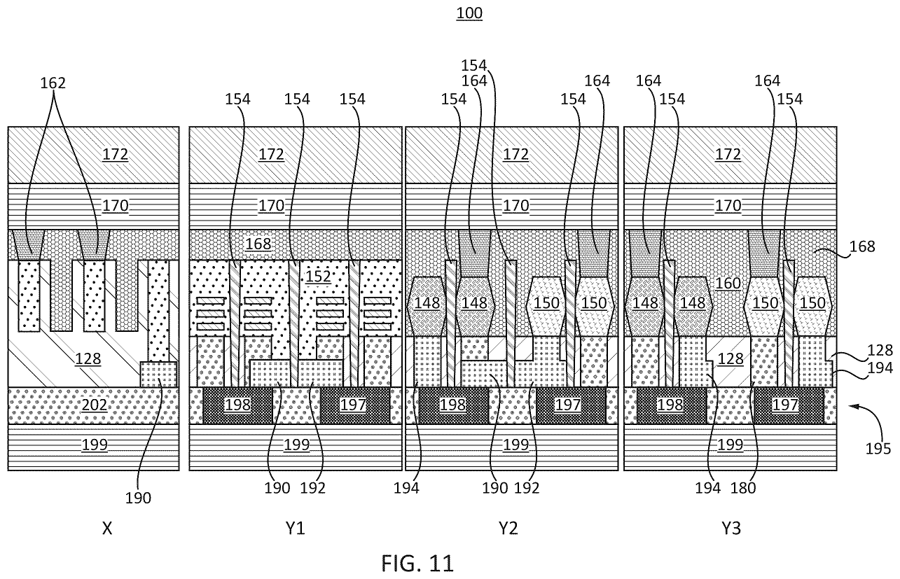

Referring to FIG. 11, processing continues with the formation of a backside interconnect layer 195, which can include metal structures and dielectric layers to complete the bottom side of the device and provide electrical access to the devices formed. The backside interconnect layer 195 is formed on the dielectric layer 180. A dielectric layer 202, which can include a same material as dielectric layer 180 is deposited and can be planarized. The dielectric layer 202 is patterned using lithography to define openings for backside power rails 197 and 198. The backside power rails 197, 198 are formed using a damascene process. A conductive fill is performed using any suitable deposition process, e.g., physical vapor depositing (PVD), CVD, PECVD, ALD, etc. The conductive fill can include materials, such as, e.g., Co, Cu, Ru, Mo, Rh, W, Ir, and alloys or combinations of these and other conductive materials. The conductive fill is planarized, e.g., by CMP, to form backside power rails 197, 198. The backside power rails 197, 198 are formed in contact with the local interconnects 190, local interconnects 192 and the backside contacts 194.

In accordance with an illustrative embodiment, backside power rail 197 provides VSS to NFETs (regions 148) while backside power rail 197 provide VDD to PFETs (regions 150). Local interconnect 190 connects to backside power rail 198, and local interconnect 192 connects to backside power rail 197.

A backside power distribution network (BSPDN) 199 is fabricated on the dielectric layer 202 and connections are made to the backside power rails 197, 198 from the BSPDN 199. Processing continues to complete the device.

In accordance with embodiments of the present invention, gate tie-downs to NFETs and PFETs within a tight transistor to transistor (T2T) region are achieved without impact to wire routing or either top side or bottom side wiring structures. In addition, local interconnects are provided that connect directly to back side power rails through a location or region between NFET-PFET (N2P). The present embodiments make connecting the gate by a gate tie-down to a backside power distribution network (BSPDN) easily achievable and reliable especially in view of decreasing node sizes.

Exemplary applications/uses to which the present invention can be applied include but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher-level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a gate metal;
a gate extension disposed within a region between two transistors of opposite conductivity and connected to the gate metal, the gate extension extending toward a side of the semiconductor device having power rails;
a gate cut disposed within the gate metal and through the gate extension to cut the gate extension into portions that are electrically isolated from each other; and
each of the portions of the gate extension is coupled to a backside power rail.

2. The semiconductor device as recited in claim 1, wherein the gate extension is disposed within a shallow trench isolation.

3. The semiconductor device as recited in claim 1, wherein each of the portions of the gate extension is connected to a local interconnect.

4. The semiconductor device as recited in claim 3, wherein the local interconnect connects a portion of the gate extension to a corresponding backside power rail.

5. The semiconductor device as recited in claim 4, wherein the gate extension extends toward a back side of the semiconductor device, and the local interconnects are disposed within a layer for back side contacts.

6. The semiconductor device as recited in claim 4, wherein a source/drain region connected to a top side contact is separated from the local interconnects by a backside interlevel dielectric layer.

7. The semiconductor device as recited in claim 1, further comprising source/drain regions of the two transistors of opposite conductivity having the gate cut disposed therebetween.

8. A semiconductor device, comprising:
an N-type field effect transistor (NFET);
a P-type field effect transistor (PFET) disposed adjacent to the NFET;
a gate metal disposed in a region between the NFET and the PFET;
a gate extension disposed within the region between the NFET and the PFET and connected to the gate metal on a back side of the semiconductor device; and
a gate cut disposed through the gate metal, and through the gate extension to cut the gate extension into a first portion and a second portion to electrically isolate the first portion from the second portion; and
the first portion being coupled to a first backside power rail and the second portion being coupled to a second backside power rail.

9. The semiconductor device as recited in claim 8, wherein the gate extension is disposed within a shallow trench isolation.

10. The semiconductor device as recited in claim 8, wherein the first portion of the gate extension connects to a supply voltage backside power rail through a local interconnect.

11. The semiconductor device as recited in claim 8, wherein the second portion of the gate extension connects to a grounded backside power rail through a local interconnect.

12. The semiconductor device as recited in claim 8, wherein the gate cut is disposed between source/drain regions of the NFET and the PFET.

13. The semiconductor device as recited in claim 8, further comprising additional gate cuts disposed between source/drain regions having a same conductivity.

14. The semiconductor device as recited in claim 8, wherein the first portion is coupled to the first backside power rail with a first local interconnect and the second portion is coupled to the second backside power rail with a second local interconnect.

15. The semiconductor device as recited in claim 14, wherein the first local interconnect and the second local interconnect are disposed within a layer for backside contacts.

16. The semiconductor device as recited in claim 14, wherein a source/drain region connected to a top side contact is separated from a corresponding one of the first local interconnect and the second local interconnect by a backside interlevel dielectric layer.

17. A method for fabrication of a semiconductor device, comprising:
extending a gate electrode by forming a gate extension into a shallow trench isolation (STI) region at an NFET to PFET (N2P) boundary;
cutting the gate extension into portions by forming a gate cut through the gate extension to divide the gate extension;
forming backside local interconnects to connect to the portions of the gate extension; and
forming power rails to connect to the backside local interconnects to tie-down the gate electrode.

18. The method as recited in claim 17, wherein the backside local interconnects are formed by depositing a conductor in an opening separated by the gate cut.

19. The method as recited in claim 17, further comprising forming additional gate cuts disposed between source/drain regions having a same conductivity.

20. The method as recited in claim 17, wherein the backside local interconnects are formed within a layer for backside contacts and a source/drain region connected to a top side contact is separated from a corresponding backside local interconnect by a backside interlevel dielectric layer.
